(19) United States
(12) Patent Application Publication
(10) Pub. No.: US 2025/0174501 A1
(43) Pub. Date: May 29, 2025

(54) PROBING BUMP PLACEMENT OVER MULTIPLE VIA OPENINGS

(71) Applicant: XILINX, INC., San Jose, CA (US)

(72) Inventors: Andy WIDJAJA, Singapore (SG); Lik Huay LIM, Singapore (SG); Mohsen H. MARDI, Saratoga, CA (US)

(21) Appl. No.: 18/955,725

(22) Filed: Nov. 21, 2024

Related U.S. Application Data
(60) Provisional application No. 63/602,495, filed on Nov. 24, 2023.

(51) Int. Cl. H01L 21/66; H01L 23/00

(52) U.S. Cl. CPC H01L 22/32; H01L 22/14; H01L 24/80; H01L 2224/80003; H01L 2224/80895; H01L 2224/80896; H01L 2224/80908

(57) ABSTRACT

A method for probing power contact pads on an integrated circuit (IC) die are disclosed. The method includes depositing a probing bump over multiple vias. The vias may be directly exposed or include an exposed contact pad. The method also includes forming a probing bump over and in electric contact with multiple vias. Optionally, the probing bump may be removed after probing.

### CROSS REFERENCE TO RELATED APPLICATION

This application claims priority to the U.S. Provisional Patent Application Ser. No. 63/602,495 filed Nov. 24, 2023 of which is incorporated herein by reference in its entirety.

### TECHNICAL FIELD

Embodiments of the present disclosure generally relate to integrated circuit (IC) dies and devices, and techniques for manufacturing the same. In particular, to an IC die that utilizes ganged contact pads contacted by a single probe pin during the IC die fabrication process.

### BACKGROUND

Electronic devices, such as tablets, computers, server, in-door telecom, out-door telecom, industrial computers, high performance computing data centers, copiers, digital cameras, smart phones, control systems and automated teller machines, among others, often employ electronic components which leverage chip package assemblies for increased functionality and higher component density. Conventional chip package assemblies include one or more stacked components such as integrated circuit (IC) dies, through-silicon-via (TSV) interposer, and a package substrate, with the chip package itself stacked on a printed circuit board (PCB). The IC dies may include memory, logic, MEMS, RF or other IC device.

With progressive decreases in technologies nodes, conventional IC die stacking and contact pad spacing has presented new challenges. For example, moving to N2 technology node requires the use of hybrid bonds for Active-On-Active (AoA) die stacking. AoA stacking requires the use of many signal transfers between upper die to lower die. This results in many signal contact pads to be placed around power contact pads. Die-to-die signals do not require probing, but power contact pads require probing at wafer sort. Large metal (either aluminum or copper) pads are used as base for placement of probing bumps in existing wafers fabricated in the N7 technology node where there is still enough room for these large pads. However, in smaller technology nodes, these large pads take up too much space and will consume the space needed for many signal contact pads. Thus, traditional large power contact pads will displace many signal contact pads is used in smaller technology nodes.

Thus, there is a need for an improved IC die and methods for fabricating the same.

### SUMMARY

An integrated circuit device and methods for fabricating the same are provided herein that have multiple contact pads coupled to a common probing bump. The common probing bump may be removed after probing, or utilized as part of the integrated circuit device.

In one example, a method for fabricating an integrated circuit device is provided that includes: depositing a first passivation layer over a surface of a structure having a plurality of first pads and a plurality of second pads, the first passivation layer masking the plurality of second pads while having openings exposing the plurality of first pads; filing the openings with a conductive material to form a plurality of conductive vias in electrical contact with the first pads; forming a conductive pillar above and in electrical contact with two or more of the conductive vias; probing the first pads through the conductive pillar; and removing the first passivation layer and the conductive pillar to expose the plurality of first pads and the plurality of second pads.

In another example, a method for fabricating an integrated circuit device is provided that includes: forming a hybrid bonding layer over a surface of a first integrated circuit die having a plurality of signal contact pads and power contact pads, the hybrid bonding layer masking hybrid bonding pads electrically connected to the plurality of signal contact pads and the plurality of power contact pads; depositing a passivation layer over the hybrid bonding layer, the passivation layer masking the hybrid bonding pads connected to the plurality of signal contact pads while having conductive vias connected to the plurality of power contact pads; and forming a probing bump above and in electrical contact with two or more of the conductive vias.

In yet another example, an integrated circuit device is provided. The integrated circuit device includes an integrated circuit (IC) die, a hybrid bonding layer, a passivation layer, and probing bump. The hybrid bonding layer is formed on the IC die. The hybrid bonding layer includes hybrid contact pads that are coupled to ground contact pads, signal contact pads, and power contact pads of the IC die. The passivation layer is formed on the hybrid bonding layer. The passivation layer masks the hybrid contact pads that are coupled to signal contact pads of the IC die. The probing bump is formed on and is electrically connected to conductive vias extending through the passivation layer. The probing bump is coupled to two or more of the ground contact pads or two or more of the power contact pads of the IC die.

### BRIEF DESCRIPTION OF DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1, 2, 3, and 4 are schematic side views of a wafer during different stages of fabricating a plurality of integrated circuit (IC) dies.

FIGS. 3A, 3B and 3C are top schematic views of probing bumps disposed on a portion of a top surface of the wafer, the probing bumps connected to only predefined types of contact pads of the IC dies.

FIG. 5 is a schematic side view of two IC dies of the wafer hybrid bonded together. The hybrid bonded IC dies are singulated to form an IC die stack from the wafer.

FIG. 6 is a schematic side view of a chip package having at least one IC die stack.

FIG. 7 is a flow diagram of a method for forming a chip package having an IC die stack.

FIG. 8 is a flow diagram of a method for forming a structure having multiple contact pads coupled to a probing bump.

FIGS. 9-13 are schematic side views of the structure during different stages of fabrication.

To facilitate understanding, identical reference numerals have been used, where possible, to designate identical elements that are common to the figures. It is contemplated that elements of one embodiment may be beneficially incorporated in other embodiments

### DETAILED DESCRIPTION

Methods for fabricating an integrated circuit (IC) device, an IC die configured for probe testing, and an IC device are described therein. Although the following description and drawings are primarily detailed at a wafer level, it is to be understood that the method described herein may be practiced before or after singulation of IC dies from an original or reconstituted wafer.

In one example, the method includes probing power and/or power contact pads on an integrated circuit (IC) die. As stated above, the IC die may be probed post (e.g., after) singulation, or while the IC die is part of an original or reconstituted wafer. The IC die is probed using probing bumps formed on a passivation layer, the passivation layer formed on a hybrid bonding layer disposed on the IC die. The passivation layer masks the signal contact pads, thus allowing more room for probing bumps connected to ground and/or power contact pads. At least one of the probing bumps is coupled to multiple power contact pads or multiple ground contact pads, thus enabling larger probe tips to be utilized while desirably maintaining a small pitch, such as less than 22 um between contact pads. The probing bumps can then be probed for IC die testing without undesirably contacting the signal contact pads since the signal contact pads are covered by the passivation layer. After probing, the probing bumps are removed. In some examples, the passivation layer may remain and become part of the IC structure. In other examples, the passivation layer is removed to allow the hybrid bonding layer to be revealed for stacking with another IC die.

Thus, the novel process disclosed herein eliminates the need for big power contact pads that are traditionally used for probing bumps used in wafer sort. For example, conventional power contact pads are about ten times the diameter of the power contact pads utilized in the present invention. Such large power contact pads would require the elimination of 2-10 columns of signal contact pads if used in 2N technology. As such the above described technique avoids displacement of signal contact pads that are required for hybrid bonds in N2 die stacking. This results in minimal or no disruption to the silicon design on the top RDL layer, and at the same time, allows for sufficient area to interface with conventional probes on probing bumps at wafer sort. After wafer sort, the probing bumps and top passivation layers are removed, allowing growth of hybrid bonds to facilitate AoA die stacking.

In other examples, a signal contact pad masking passivation layer and probing bumps that each covers multiple power contact pads may be disposed on a hybrid bonding layer and used for wafer probing, then removed to re-expose the hybrid bonding layer for subsequent bonding to another structure, such as a second wafer. In yet another example, this technique of covering multiple power (or other) pads with a single probe bump must also be used on just about any semiconductor surface having multiple exposed pads, such as a wafer surface, an integrated circuit (IC) die surface, an IC chiplet surface, an interposer surface, a redistribution layer or fan-out surface, a hybrid bonding surface, a package substrate surface or a printed circuit board surface, among others.

Throughout this disclosure the term “pad” is utilized to mean either a contact or bond pad, or an exposed end of a via.

In one example, a probing bump that covers multiple power vias is fabricated on hybrid bonding layer is disposed on a wafer and used for probing the wafer. The probing bump is removed after sorting, exposing the hybrid bonding layer of the wafer for stacking to another structure.

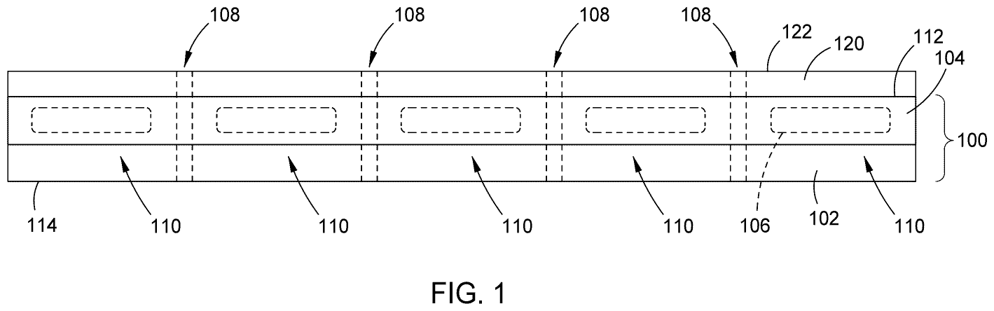

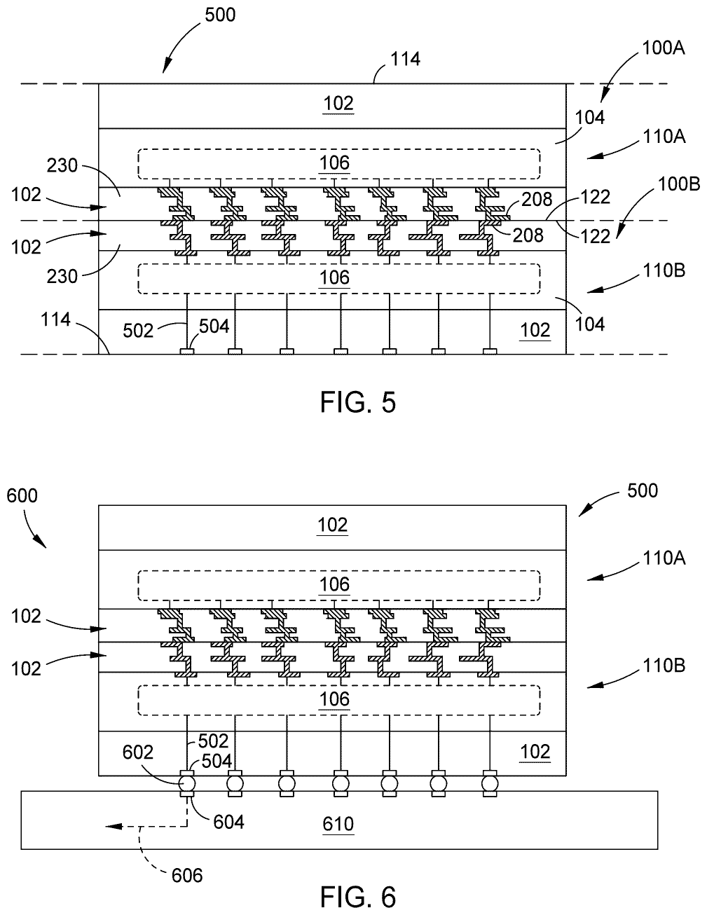

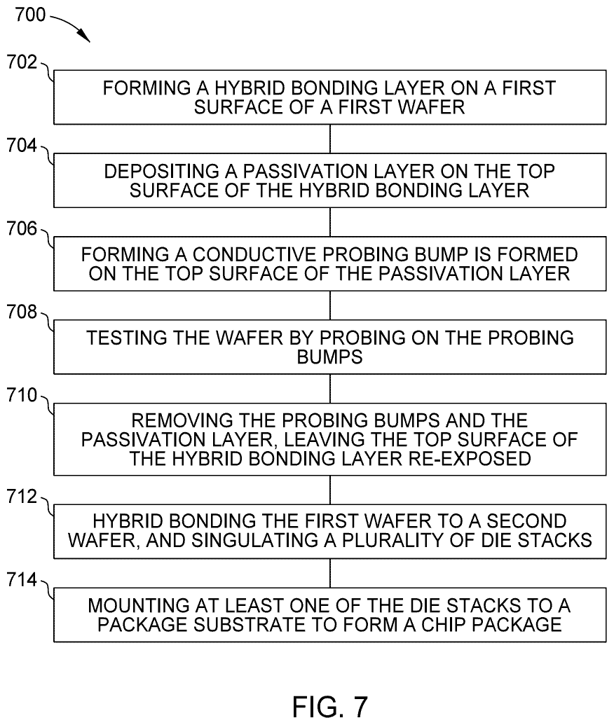

A first example of a method 700 for fabricating a chip package utilizing the attributes described above is illustrated in FIG. 7. FIGS. 1, 2, 3, 4 and 5 depict a wafer 100 during various stages at the beginning of the method 700 for fabricating a chip package. FIG. 5 depicts two IC dies of two stacked wafers 100 hybrid bonded together during a portion of the method 700, while FIG. 6 depicts a schematic side view of a chip package having at least one IC die stack formed during the method 700.

The method 700 begins at operation 702 by forming a hybrid bonding layer 120 on a top surface 112 of a wafer 100, as illustrated in FIG. 1. The wafer 100 includes a substrate 102 and an active layer 104. The active layer 104 is formed on the substrate 102. The substrate 102 illustrated in FIG. 1 is a silicon wafer, but may alternatively be another type of substrate, such as glass, plastic, gallium arsenide, silicon carbide, and indium phosphide, among others. The active layer 104 includes back end of the line (BEOL) regions and front end of the line (FEOL) regions.

The wafer 100 generally includes a plurality of integrated circuit (IC) dies 110. The IC dies 110 are generally separated by one another by scribe lanes 108. During dicing, a wire saw or other type of instrument is used to separate the individual dies 110. In some examples, the separated IC dies 110 may be reassembled to form a reconstituted wafer. In some examples, the IC dies 110 conforms to 2 nanometer technology as defined in the 2021 update of the International Roadmap for Devices and Systems published by the Institute of Electrical and Electronics Engineers.

The active layer 104 of each IC die 110 includes functional circuitry 106. The functional circuitry 106 of the IC die 110 may include central processing unit (CPU) cores. As such, the IC die 110 containing CPU cores may be referred to as a CPU die or CPU chiplet. The functional circuitry 106 may also include System Management Unit (SMU). The SMU is circuitry configured to monitor thermal and power conditions and adjust power and cooling to keep the IC die 110 functioning as within specifications. The functional circuitry of the IC die 110 may also include Dynamic Function exchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition. In the DFX circuitry, the “X” represents various purposes, such as DFD (Design for Debug), DFM (Manufacturability), DFR (Reliability), DFT (Test), and DFY (Yield), among others. In another example, the functional circuitry 106 of the IC die 110 includes accelerated compute cores. As such, the IC die 110 containing accelerated compute cores may be referred to as an accelerator die or accelerator chiplet. The IC die 110 containing accelerated compute cores may also be referred to as a graphic processing unit (GPU) die or GPU chiplet. The accelerated compute cores contained in the functional circuitry 106 generally includes math engine circuitry. The math engine circuitry is generally designed for task specific computing, such as used data center computing, high performance computing and Al/ML computing. Along with the accelerated compute cores, functional circuitry 106 of the IC die may also include SMU circuitry and DFX circuitry, as mentioned above.

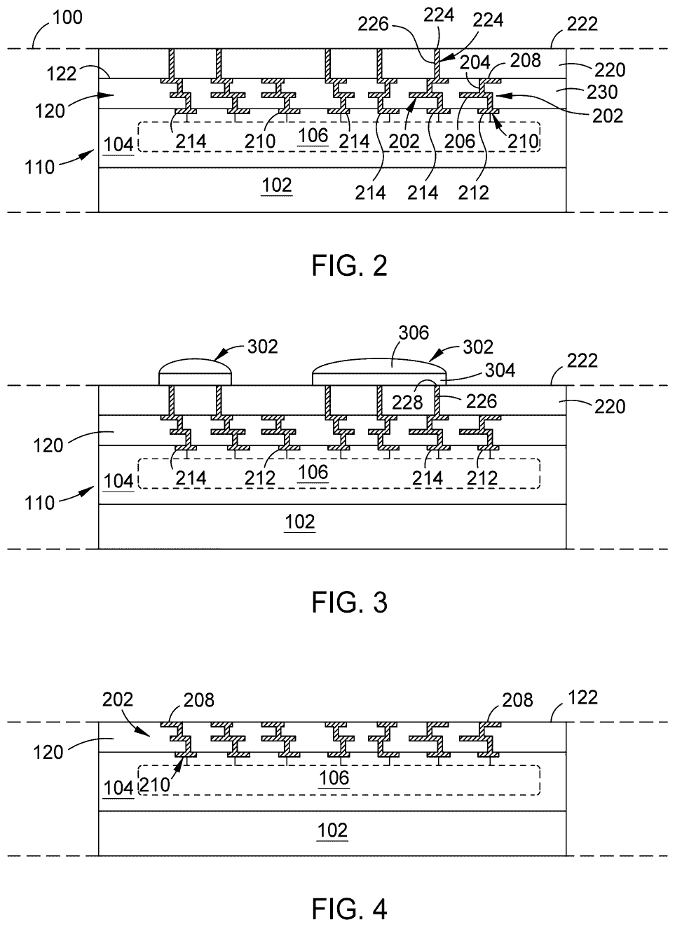

The functional circuitry 106 of the IC die 110 terminates at contact pads. The contact pads (210 later shown in FIG. 2) are exposed on the top surface 112 of the active layer 104 of the IC die 110. The contact pads are generally arranged in rows and columns. In one example, spacing (e.g., pitch) between the contact pads conforms to 2 nanometer technology as defined in the 2021 update of the International Roadmap for Devices and Systems published by the Institute of Electrical and Electronics Engineers. In some examples, the rows and columns of contact pads are disposed in an X/Y grid pattern. In other examples, contact pads in one row and/or column may be offset or staggered relative to the contact pads of other rows and/or columns. Stated differently, the arrangement of contact pads on the top surface 112 of the active layer 104 may have any other desirable pattern or arrangement. The contact pads may have a rectangular shape, a circular shape or any other desirable shape or pattern.

The hybrid bonding layer 120 completely covers and thus buries the top surface 112 of the active layer 104.

At operation 704, a passivation layer 220 is deposited on the top surface 122 of the hybrid bonding layer 120, as illustrated in FIG. 2. The passivation layer 220 includes an exposed top surface 222 that faces away from the substrate 102. The passivation layer 220 completely covers and thus buries top surface 122 of the hybrid bonding layer 120.

The passivation layer 220 may be formed from one or more dielectric layers. The passivation layer 220 may be fabricated from silicon nitride, polyimide or other suitable dielectric material. A plurality of openings 224 are disposed through the passivation layer 220. Each of the openings 224 is filled with a conductive via 226. The conductive via 226 may be formed from aluminum, copper or other suitable electrically conductive material. The conductive via 226 have an end 228 that is exposed through the top surface 222 of the passivation layer 220. The exposed end 228 of the conductive via 226 may be coplanar with the top surface 222 of the passivation layer 220.

Some of the conductive vias 226 may be electrically floating and located within the passivation layer 220 to enhance warpage resistance. However, most of the conductive via 226 are coupled to the functional circuitry 106 of the IC die 110 through routing 202 formed through the hybrid bonding layer 120.

The routing 202 formed through the hybrid bonding layer 120 generally includes patterned lines 206 and vias 204 formed in one or more layers of dielectric material 230. The lines 206 and vias 204 of the routing 202 may be made from copper, aluminum, or other suitable electrically conductive material. The dielectric material 230 may be an oxide, thermal oxide, SiO₂, SiN, SiCN, polybenzoxazole (PBO), polyimide (PI), benzocyclobutene (BCB), among other materials that allow fusion bonding of the top surface 222 of the dielectric material 230 with a hybrid bonding layer of an adjacent IC die, as later discussed below.

An end of metal routing 202 formed through the dielectric material 230 terminates at a hybrid contact pad 208, while the opposite end of the metal routing 202 terminates and is electrically connected to a contact pad 210 formed in the top surface 112 of the active layer 104. Some of the contact pads 210 are configured to transmit data signals to and from the functional circuitry 106 of the IC die 110. Some of the contact pads 210 are configured to connect power to the functional circuitry 106 of the IC die 110, while other contact pads 210 are configured to connect ground to the functional circuitry 106 of the IC die 110. The contact pads 210 that are configured to connect power to the functional circuitry 106 of the IC die 110 may be referred to as power contact pads 214. The contact pads 210 that are configured to connect ground with the functional circuitry 106 of the IC die 110 may be referred to as ground contact pads (which may also be designated by reference numeral 214).

As illustrated in FIG. 2, only the exposed ends 228 of the conductive vias 226 formed through the passivation layer 220 are coupled to the contact pads 214, while the signal contact pads 212 remaining buried, and thus, electrically dead ended below the passivation layer 220. Stated differently, the signal contact pads 212 are dead-ended and buried below the passivation layer 220. Although only a few signal contact pads 212 are illustrated in FIG. 1, the many more signal contact pads 212 may be utilized, and generally many more signal contact pads 212 are utilized compared to the number of ground and power contact pads 214.

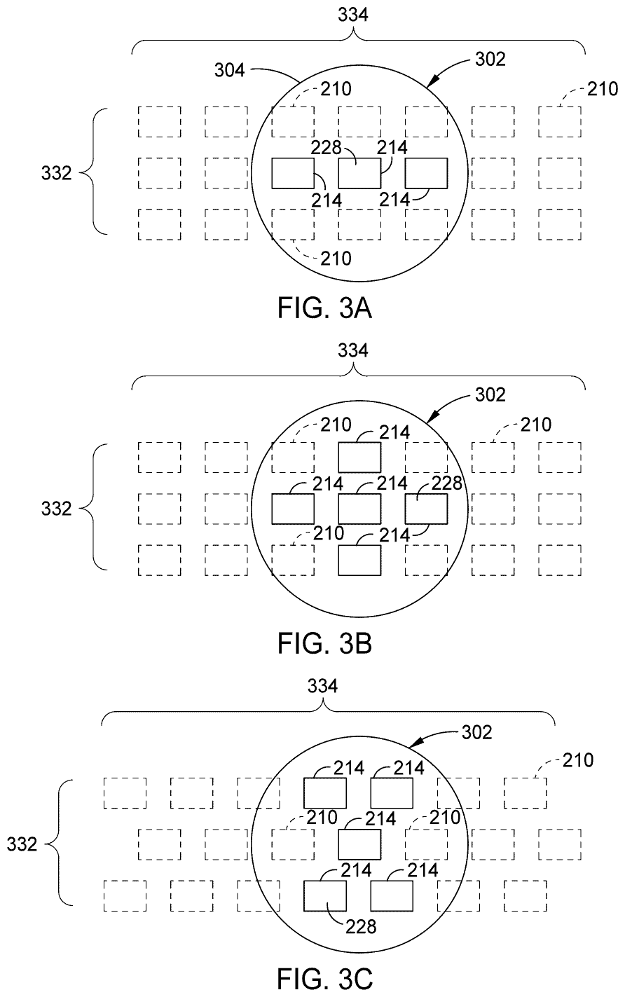

At operation 706, a conductive probing bump 302 is formed on the top surface 222 of the passivation layer 220 as illustrated in FIG. 3. The probing bump 302 is electrically connected to the contact pads 214 by the vias 226 formed through the passivation layer 220. As none of the signal contact pads 212 are connected by vias 226 to the top surface 222 of the passivation layer 220, no signal contact pad 212 is coupled to probing bump 302.

The probing bump 302 generally includes a conductive pillar 304 that in formed on the exposed end 228 of the via 226. The probing bump 302 may alternatively be a solder bump or other conductive structure. The conductive pillar 304 is grown on top of the passivation layer 220 with connections through the vias to only the hybrid contact pad 208 that are coupled to power and/or ground contact pads 214, as the hybrid contact pad 208 that are coupled to the signal contact pads 212 remain masked by the passivation layer 220, as shown in FIG. 3. The conductive pillar 304 may be formed from copper, aluminum, another suitable electrically conductive metal, or other suitable electrically conductive material.

A solder cap 306 may be disposed on the conductive pillar 304 for interfacing with the tip of the test probe. The solder cap 306 may alternatively be a solder bump or other conductive structure.

The number of vias 226 connected to a common probing bump 302 may vary. In the example depicted in FIG. 3, three vias 226 are illustrated coupled to a single common probing bump 302. However, the number, size, shape and pattern of the vias 226 connected to a single common probing bump 302 may vary from 2 or more, to as many can desirably fit below the probing bump 302.

FIGS. 3A, 3B and 3C are top schematic views of probing bumps 302 disposed on a portion of a top surface 222 of the wafer 100, where the probing bumps 302 are connected to only predefined types of contact pads (e.g., power or ground contact pads of the IC dies 110.

Referring first to FIG. 3A, each probing bump 302 covers multiple hybrid power contact pads 308 that are connected by the vias 226 to the power contact pads 214 such that the group of the power contact pads 214 and vias 226 disposed under a common probing bump 302 are electrically connected in parallel. The contact pads 210 are arranged in rows 332 and columns 334.

In one example, the single probing bump 302 shown in FIG. 3A covers at least two hybrid power contact pads 208, and as such, is connected to at least two power contact pads 214. In another example, a single probing bump 302 covers three, four, five, six or more hybrid power contact pads 208 that are coupled to a corresponding number of power contact pads 214. The power contact pads 214 connected to a single probing bump 302 may be aligned in a row or column (as shown in FIG. 3A), arranged in a grid, arranged in a honeycomb pattern, or arranged in another pattern. In one example, 2 or more, 4 or more, 6-12 or more power contact pads 214 and their corresponding vias 226 are covered by a single probing bump 302.

The probing bump 302 also covers multiple signal contact pads 212 and hybrid pads 208 coupled thereto. The signal contact pads 212 and their corresponding hybrid pads 208 are buried below the passivation layer 220, and thus, electrically dead-ended. Due to the passivation layer 220, the covered signal contact pads 212 are not electrically connected (e.g., are electrically isolated from) the probing bump 302 under which the covered signal contact pads 212 reside. In other examples, signal contact pads from two or more adjacent columns of signal contact pads are covered by a single probing bump 302.

For example depicted in FIG. 3B, the probing bump 302 covers multiple signal contact pads 212 and hybrid pads 208 coupled thereto that reside in multiple rows 332 and multiple columns 334. FIG. 3C illustrates probing bump 302 covers multiple signal contact pads 212 and hybrid pads 208 coupled thereto that reside in multiple rows 332 and multiple columns 334, wherein at least one or both of the rows 332 and columns 334 have signal contact pads 212 and/or hybrid pads 208 that are offset from their corresponding signal contact pads 212 and/or hybrid pads 208 residing in another one of the rows 332 and columns 334.

Although the probing bumps 302 are illustrated in FIGS. 3A, 3B and 3C as having a circular shape, the probing bump 302 may have a rectangular shape, oval shape, hexagonal shape, or any other desirable shape or pattern. Additionally, although the probing bumps 302 are illustrated in FIGS. 3A, 3B and 3C as being connected to power contact pads, the probing bumps 302 may alternatively be coupled to ground contact pads in the same manner.

Returning to the fabrication method 700 depicted in FIG. 7, the method 700 continues at operation 708 by testing the wafer 100. The wafer 100 will then undergo wafer sort testing by probing on the probing bumps 302. The wafer 702 is generally tested by an automatic testing device (ATD). A single probe of the ATD applies power to multiple power contact pads 214 of the IC die 110 through contact of a single probing bump 302. In the alterative or additionally, multiple ground contact pads 214 may be tested via a single probing bump 302 by the ATD.

After testing, the method 700 continues to operation 710 by removing the probing bumps 302 and the passivation layer 220, leaving the top surface 122 of the hybrid bonding layer 120 re-exposed, as illustrated in FIG. 4. The probing bumps 302 and the passivation layer 220 may be removed by chemical mechanical polishing, lapping, grinding, milling and/or chemical etching process and/or other suitable technique. The passivation layer removal operation 710 results in the re-exposed top surface 122 of the hybrid bonding layer 120 having a surface roughness that is much smoother and polished relative to the original to top surface 122 prior to the deposition of the passivation layer 220.

At operation 712, a first wafer 100A is hybrid bonded to a second wafer 100B, as illustrated in FIG. 5. The wafers 110A, 110B are stacked active side to active side. The hybrid bonds on the active sides of the wafers 110A, 110B include non-metal to non-metal bonds formed by fusion bonding, and metal-to-metal bonds formed across the adjacent wafers 100A, 100B. The top surface 222 of the dielectric material 230 of the hybrid bonding layer 120 of the first wafer 100A is fusion bonded to the dielectric material 230 of the hybrid bonding layer 120 of the second wafer 100B. The hybrid contact pad 208 exposed on the facing top surfaces 222 of the adjacent wafers 100A, 100B then form metal-to-metal bonds using pressure and heat to form eutectic metal bonds that couple the functional circuitry 106 of the adjacent IC dies 110 respectively disposed in the adjacent wafers 100A, 100B. In one example, a hybrid bond is formed by bonding the dielectric materials 230 surrounding the hybrid contact pad 208 on each IC die 110 to first secure the IC dies 110 together, followed by an interfusion of the metal materials of the hybrid contact pad 208 of the facing IC dies 110 to create the electric interconnect between the functional circuitry 106 of the one IC die 110 and the functional circuitry 106 of the vertically adjacent IC die 110. After hybrid bonding, the IC dies 110 may be singulated into die stacks 500, where each die stack 500 includes at least to IC dies 110 hybrid bonded together.

At least one of the IC dies 110 of the die stack 500 includes a plurality of through silicon vias (TSVs) 502 that couple the functional circuitry 106 to bond pads 504 located on the bottom surface 114 of the IC die 110. Optionally, both of the IC dies 110 of the die stack 500 may include bond pads 504 located on the bottom surfaces 114 of the IC dies 110.

At operation 714, the die stack 500 may be mounted to a package substrate 610 to form a chip package 600, as illustrated in FIG. 6. In one example, the bond pads 504 located on the bottom surface 114 of one of the IC dies 110 is coupled to bond pads 604 exposed on the top surface of the package substrate 610. The bond pads 504, 604 may be coupled using a socket, solder balls, or by another technique. In the example depicted in FIG. 6, the pads 504, 604 are coupled using solder balls 602, thus connecting routing 606 of the package substrate 610 to the functional circuitries 106 of the IC dies 110.

In one example, a probing bump that covers and it coupled to multiple power vias is fabricated on a pad (or via) exposed on a structure, and used for probing the routing of the structure connected to the probing bump. The structure may be a surface having multiple exposed pads (or vias), such as a wafer surface, an integrated circuit (IC) die surface, an IC chiplet surface, an interposer surface, a redistribution layer or fan-out surface, a hybrid bonding surface, a package substrate surface or a printed circuit board surface, among others. The probing bump can be removed after sorting, exposing the pad of the structure for stacking to another structure, or forming solder bumps for connecting to another structure. The probing bump can alternately remain in the structure after sorting, and be used for connecting to another structure, communication connector, or device.

In another example, a probing bump that covers and is coupled to multiple power vias is fabricated on a pad (or via) exposed on a structure, and used for probing the routing of the structure connected to the probing bump. The probing bump may alternatively be coupled to multiple ground via. The structure may be a surface having multiple exposed pads (or vias), such as a wafer surface, an integrated circuit (IC) die surface, an IC chiplet surface, an interposer surface, a redistribution layer or fan-out surface, a hybrid bonding surface, a package substrate surface or a printed circuit board surface, among others. The probing bump can be removed after sorting, exposing the pad of the structure for stacking to another structure, or forming solder bumps for connecting to another structure. The probing bump can alternately remain in the structure after sorting, and be used for connecting to another structure, communication connector, or device.

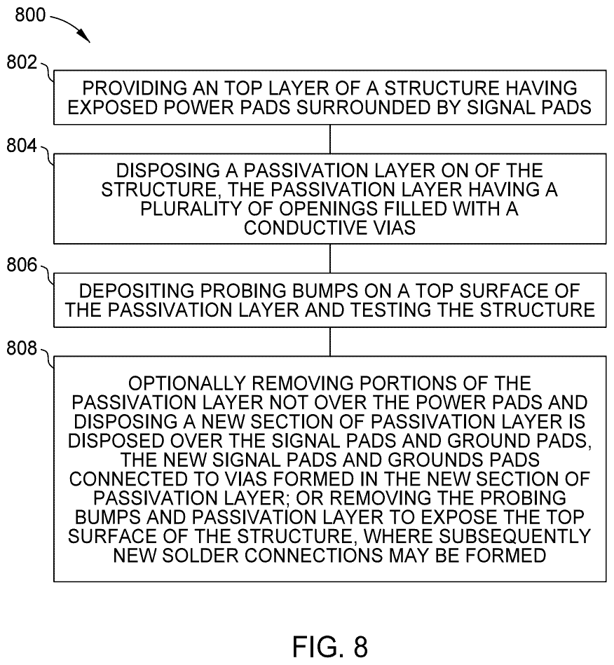

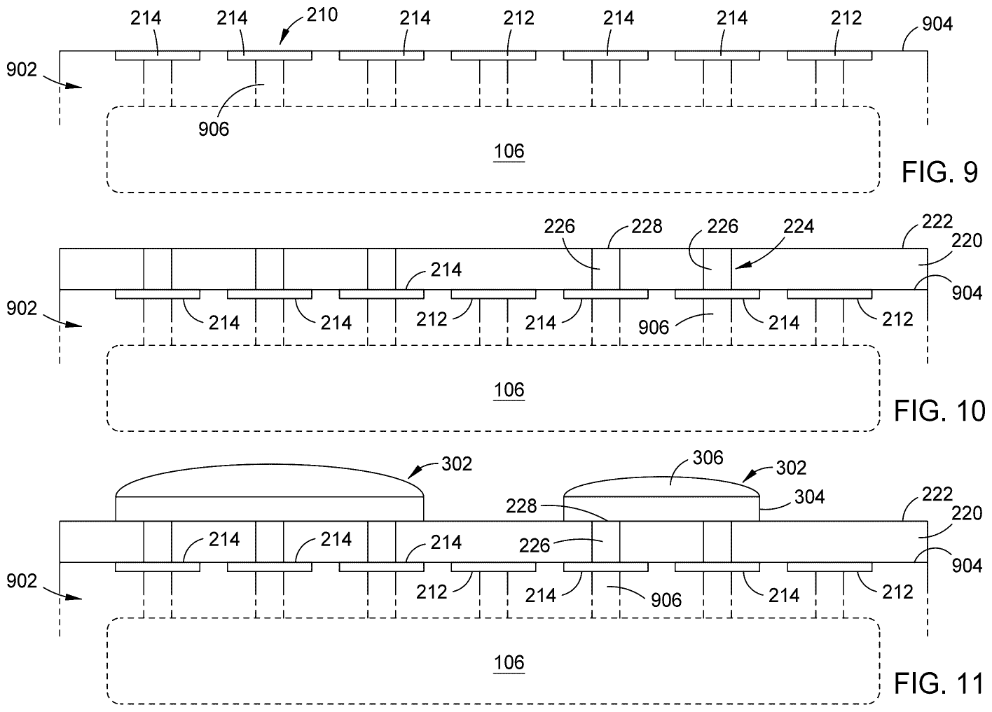

FIG. 8 depicts a flow diagram of a method 800 for forming a structure 902 having, at during testing, masked signal contact pads and at least one group of ground and/or power contact pads coupled to a common conductive probing bump 302. As discussed above, the structure 902 may be wafer, an integrated circuit (IC) die, an IC chiplet, an interposer, a redistribution layer or fan-out structure, a hybrid bonding layer, a package substrate or a printed circuit board, among others. The method 800 begins at operation 802 with a top layer 904 (i.e., exposed surface of the structure 902) having exposed power contact pads 214 surrounded by signal contact pads 212, as shown in FIG. 9. Ground contact pads, although not shown in FIG. 9, are also present on the top layer 904. It is also to be understood that the method 800 may be practice where ground contact pads replace the power contact pads 214 shown in FIG. 9. The power contact pads 214 generally may alternatively be another type of pad connected to a circuit/routing to be tested in the structure 902, while the signal contact pads 212 alternatively be another type of pad connected to a circuit/routing in the structure that is not to be tested while other circuit/routing of the structure 902 is being tested.

The signal contact pads 212, the power contact pads 214, and the round pads (not shown) are coupled by routing 906 to functional circuitry 106. The functional circuitry 106 may reside in the structure 902, more may reside in an adjacent electrically connect component of a common chip package (such as an IC die 110 or chip package 600) or other device.

At operation 804, a passivation layer 220, as shown in FIG. 10, is disposed on the structure 902. A plurality of openings 224 are disposed through the passivation layer 220. The openings 224 are filled with a conductive via 226. exposing only the power contact pads 214. The signal contact pads 212 and ground contact pads are masked by the passivation layer 220.

At operation 806, probing bumps 302 are disposed on the top surface 222 of the passivation layer 220, as illustrated in FIG. 11. The probing bumps 302 are connected by the vias 226 disposed through the openings 224 to only the power contact pads 214, as the signal and ground contact pads remain masked by the passivation layer 220, as shown in FIG. 11. The probing bumps 302 may include a metal pillar 304 that is formed from copper, aluminum or other suitable electrically conductive material. The probing bumps 302 may also include a solder cap 306 disposed on the pillar 304 for interfacing with the tip of the test probe. The probing bump 302 may alternatively be a solder bump or other conductive structure.

As illustrated in FIG. 11, each probing bump 302 covers multiple power contact pads 214 such that the covered power contact pads 214 are electrically connected in parallel. In one example, the probing bump 302 covers at least two power contact pads 214. In another example, a single probing bump 302 covers three, four, five, six or more power contact pads 214. The power contact pads 214 covered by a single probing bump 302 may be aligned in a row or column, arranged in a grid, arranged in a honeycomb pattern, or arranged in another pattern. Some patterns are illustrated in FIGS. 3A, 3B and 3C, among others.

The probing bump 302 may optionally covers multiple signal contact pads 212. In one example, 2 or more, 4 or more, 6-12 or more signal contact pads 212 are covered by a single probing bump 302. Due to the passivation layer 220, the covered signal contact pads 212 are not electrically connected (e.g., are electrically isolated from) the probing bump 302. In other examples, signal contact pads 212 from two or more adjacent columns of signal contact pads 212 are covered by a single probing bump 302.

The structure 902 is then tested by probing on the probing bumps 302 to test the circuitry/routing connected to the power contact pads 214. The testing may include a sort between structures 902 passing and failing the test. Alternatively, the probing bumps 302 may be coupled to ground contact pads instead of the power contact pads 214 for testing the ground circuitry.

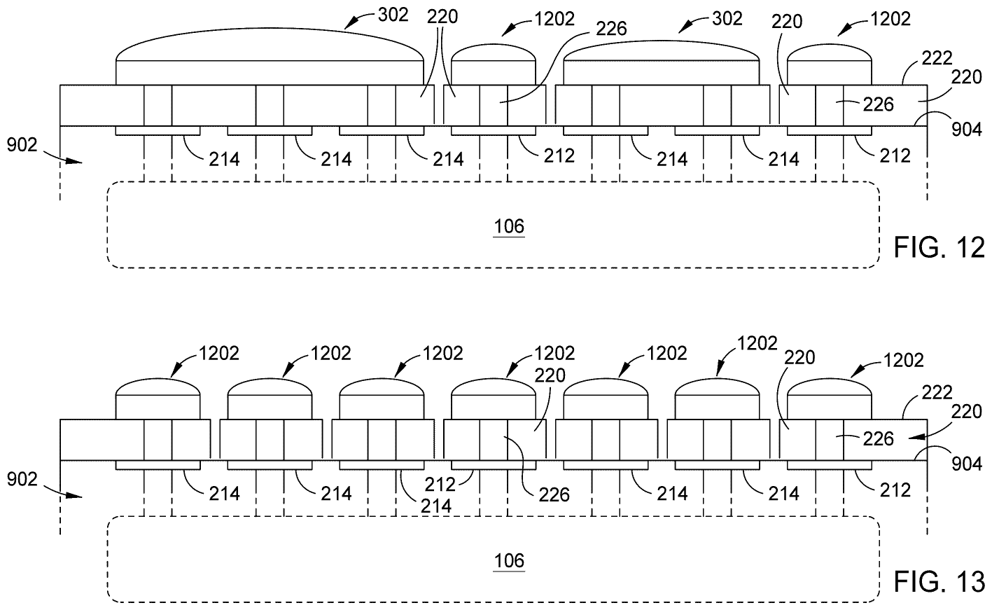

In one example after testing, portions of the passivation layer 220 not over a signal, ground or power contact pad are removed at an optional operation 808, for example by etching, while the probing bumps 302 remain, as shown in FIG. 12. In the remaining portions of the passivation layer 220 that have not been removed, additional vias 226 are formed to connect to the signal contact pads 212 and ground contact pads. A solder connection 1202 is formed on the additional vias 226, leaving the structure 902 ready for connection to another structure, connector or device.

In an alternative example at operation 808, portions of the passivation layer 220 not over the power contact pads 214 are removed. A new section of passivation layer 220 is disposed over the signal contact pads 212 and ground contact pads. New vias 226 are formed in the new section of the passivation layer 220 to connect to the signal contact pads 212 and ground contact pads. A solder connection 1202 is formed on the new vias 226, leaving the structure 902 ready for connection to another structure, connector or device.

In yet another alterative example at operation 808, the probing bumps 302 and passivation layer 220 are removed by mechanical, chemical, chemical mechanical, and/or etching process to expose the top layer 904 of the structure 902, where subsequently new solder connections 1202 coupled via vias 226 formed in a new passivation layer 220 may be formed, as shown in FIG. 13.

In each example, the probing bumps 302 and passivation layer 220 may be optionally removed and a hybrid bonding layer 120 such as described above may be formed on the top surface 902 for connecting the structure 902 to another integrated circuit structure or device via hybrid bonding techniques.

Thus as described above, the new process eliminates the need for large metal pads underneath the probing bumps. This allows silicon designers great flexibility in the placements of signal contact pads. At the same time, with this new process probing bumps can still be grown on the wafer. Wafer sort testing will benefit from being able to probe on the bigger probing bumps. This allow the probe cards to use the existing proven probe technologies with higher current carrying capacity (CCC) for the needles. This new technique allows power contact pads to be as much as about ten times smaller than conventional power contact pads, consequently enabling an improved distribution of power contact pads 2N technology. As such the above described technique avoids displacement of signal contact pads that are required for hybrid bonds in N2 die stacking.

While the foregoing is directed to specific examples, other and further examples may be devised without departing from the basic scope thereof, and the scope thereof is determined by the claims that follow.

What is claimed is:

1. A method for fabricating an integrated circuit device, the method comprising:
depositing a first passivation layer over a surface of a structure having a plurality of first pads and a plurality of second pads, the first passivation layer masking the plurality of second pads while having openings exposing the plurality of first pads;
filling the openings with a conductive material to form a plurality of conductive vias in electrical contact with the first pads;
forming a conductive pillar above and in electrical contact with two or more of the conductive vias;
probing the first pads through the conductive pillar; and
removing the first passivation layer and the conductive pillar to expose the plurality of first pads and the plurality of second pads.

2. The method of claim 1, wherein the surface of the structure comprises a hybrid bonding layer.

3. The method of claim 1, wherein the structure comprises a wafer surface, an integrated circuit (IC) die surface, an IC chiplet surface, an interposer surface, a redistribution layer or fan-out surface, a hybrid bonding surface, a package substrate surface or a printed circuit board surface.

4. The method of claim 3, further comprising:
after probing, hybrid bonding the structure to another structure.

5. A method for fabricating an integrated circuit device, the method comprising:
forming a hybrid bonding layer over a surface of a first integrated circuit die having a plurality of signal contact pads and a plurality of power contact pads, the hybrid bonding layer masking hybrid bonding pads electrically connected to the plurality of signal contact pads and the plurality of power contact pads;
depositing a passivation layer over the hybrid bonding layer, the passivation layer masking the hybrid bonding pads connected to the plurality of signal contact pads while having conductive vias connected to the plurality of power contact pads; and
forming a probing bump above and in electrical contact with two or more of the conductive vias.

6. The method of claim 5, further comprising:
probing the power contact pads through the probing bump.

7. The method of claim 6, further comprising:
after probing, removing the passivation layer to re-expose the hybrid bonding layer.

8. The method of claim 7, further comprising:
hybrid bonding the re-exposed hybrid bonding layer to a second integrated circuit die to form a stack of integrated circuit dies.

9. The method of claim 8, the stack of integrated circuit dies span two separate wafers.

10. The method of claim 9, further comprising:
singulating the stack of integrated circuit dies; and
mounting the singulated stack of integrated circuit dies to a package substrate to form a chip package.

11. The method of claim 5, wherein forming the probing bump above and in electrical contact with two or more of the conductive vias further comprises:
contacting two or more conductive vias arranged in a common column and/or a common row.

12. An integrated circuit device comprising:
an integrated circuit (IC) die having a hybrid bonding layer formed thereon, the hybrid bonding layer having hybrid contact pads that are coupled to ground contact pads, signal contact pads, and power contact pads of the IC die;
a passivation layer formed on the hybrid bonding layer and masking the hybrid contact pads that are coupled to the signal contact pads of the IC die; and
a probing bump formed on and electrically connected to conductive vias extending through the passivation layer and coupled to two or more of the ground contact pads or two or more of the power contact pads of the IC die.

13. The integrated circuit device of claim 12, wherein the conductive vias are connected to a group of the power contact pads of the IC die.

14. The integrated circuit device of claim 13, wherein the group of the power contact pads includes at least 6 or more of the power contact pads coupled to the probing bump.

15. The integrated circuit device of claim 12, wherein the conductive vias are connected to a group of the ground contact pads of the IC die.

16. The integrated circuit device of claim 13, wherein the IC die conforms to 2 nanometer technology as defined in the 2021 update of the International Roadmap for Devices and Systems published by the Institute of Electrical and Electronics Engineers.

17. The integrated circuit device of claim 12, wherein the probing bump further comprises:
a conductive pillar; and
a solder cap disposed on the conductive pillar.

18. The integrated circuit device of claim 17, wherein the conductive pillar of the probing bump is disposed in contact with the conductive vias.

19. The integrated circuit device of claim 18, wherein the conductive vias couple the probing bump to functional circuitry disposed in the IC die.

20. The integrated circuit device of claim 17, wherein the conductive pillar of the probing bump is disposed over and electrically isolated from some of the signal contact pads.
